(19) United States
(12) Patent Application Publication
(10) Pub. No.: US 2024/0251639 A1
(43) Pub. Date: Jul. 25, 2024

(54) DISPLAY DEVICE AND MANUFACTURING METHOD THEREOF

(71) Applicant: Samsung Display Co., LTD., Yongin-si (KR)

(72) Inventors: Hyo Jeong KWON, Yongin-si (KR); Seung Wook KWON, Yongin-si (KR); HEECHANG YOON, Yongin-si (KR)

(21) Appl. No.: 18/513,425

(22) Filed: Nov. 17, 2023

(30) Foreign Application Priority Data
Jan. 19, 2023 (KR) 10-2023-0008083

(51) Int. Cl. H10K 59/80; H10K 59/12

(52) U.S. Cl. CPC H10K 59/873; H10K 59/1201

(57) ABSTRACT

A manufacturing method of a display device includes: forming a display panel on a substrate; forming a protective layer on the display panel; forming protrusions and depressions on a surface of the protective layer by performing a surface treatment on the surface of the protective layer; attaching an adhesive layer and an acid resistant film on the protective layer; etching the substrate; and removing the adhesive layer and the acid resistant film.

This application claims priority to Korean Patent Application No. 10-2023-0008083, filed on Jan. 19, 2023, and all the benefits accruing therefrom under 35 U.S.C. § 119, the content of which in its entirety is herein incorporated by reference.

### BACKGROUND

### (a) Field

The disclosure relates to a display device and a manufacturing method of the display device.

### (b) Description of the Related Art

A display device is an electric device that displays an image, and recently, an emissive display device (e.g., an organic light emitting diode display) is attracting attention.

The emissive display device has self-luminous characteristics and unlike a liquid crystal display, it does not use a separate light source and thus the thickness and weight can be reduced. In addition, the emissive display device exhibits high quality characteristics such as low power consumption, high luminance, and high reaction speed.

### SUMMARY

In general, an emissive display device includes a substrate, a plurality of transistors disposed on the substrate, a plurality of insulation layers disposed between wires that form the thin film transistor, and a light emitting element connected to the thin film transistors.

In this case, it is desirable to form the substrate to have a thin thickness to be applied to various electronic devices.

Embodiments are to provide a display device and a manufacturing method thereof to prevent a protective layer from being peeled off when an acid resistant film is removed during a substrate etching process.

A manufacturing method of a display device according to an embodiment includes: forming a display panel on a substrate; forming a protective layer on the display panel; forming protrusions and depressions on a surface of the protective layer by performing a surface treatment on the surface of the protective layer; attaching an adhesive layer and an acid resistant film on the protective layer; etching the substrate; and removing the adhesive layer and the acid resistant film.

In an embodiment, the protective layer may include an ultraviolet (UV) curable resin.

In an embodiment, the forming the protective layer on the display panel may include coating the UV curable resin on the display panel and curing the UV curable resin through UV irradiation.

In an embodiment, the protective layer may have a single-layer structure or a multi-layered structure.

In an embodiment, a thickness of the protective layer may be in a range of about 10 micrometers (μm) to about 150 μm.

In an embodiment, in the forming the display panel on the substrate, a thickness of the substrate may be in a range of about 30 μm to about 70 μm.

In an embodiment, the substrate may include glass.

In an embodiment, after the forming the protrusions and depressions on the surface of the protective layer by performing the surface treatment on the surface of the protective layer, a contact angle of the protective layer may be less than about 10 degrees.

In an embodiment, the contact angle of the protective layer may be in a range of about 3 degrees to about 7 degrees.

In an embodiment, after the forming the protrusions and depressions on the surface of the protective layer by performing the surface treatment on the surface of the protective layer, a peel force of a surface-treated region may be in a range of about 1 g·f/inch to 60 g·f/inch.

In an embodiment, the surface treatment may be performed by a plasma treatment or a bead treatment.

In an embodiment, a diameter of beads used in the bead treatment may be in a range of about 5 μm to about 80 μm.

In an embodiment, beads used in the bead treatment may include at least one material selected from Si, AlOx, rubber, and a metal.

In an embodiment, in the bead treatment, an angle at which beads are sprayed on the surface of the protective layer may be in a range of about 45 degrees to about 135 degrees.

In an embodiment, after the etching the substrate, a thickness of the substrate may be in a range of about 10 μm to about 30 μm.

In an embodiment, in the forming the protrusions and depressions on the surface of the protective layer by performing the surface treatment on the surface of the protective layer, an entire region of the surface of the protective layer may be surface-treated.

In an embodiment, In the forming the protrusions and depressions on the surface of the protective layer by performing the surface treatment on the surface of the protective layer, only a partial region of the surface the protective layer may be surface-treated.

In an embodiment, the partial region where the protective layer is surface-treated may be an edge region of the protective layer including a region where the protective layer is in direct contact with the substrate.

A display device according to an embodiment includes: a substrate; a display panel disposed on the substrate; a thin film encapsulation layer disposed on the display panel; and a protective layer disposed on the thin film encapsulation layer, where a surface of the protective layer comprises protrusions and depressions, and a contact angle of the protective layer is about 10 degrees or less.

In an embodiment, a thickness of the substrate may be in a range of about 10 μm to about 30 μm.

According to embodiments, a display device and a manufacturing method thereof are provided to prevent the protective layer from being peeled off when the acid resistant film is removed during the substrate etching process.

### BRIEF DESCRIPTION OF THE DRAWINGS

FIG. 1 to FIG. 5 show a manufacturing method of a display device according to an embodiment.

FIG. 6 to FIG. 10 show a separation process when the surface of the protective layer 400 is not treated.

FIG. 11 to FIG. 15 show a method for forming a display device according to an alternative embodiment.

FIG. 16 shows a surface of the protective layer before the surface treatment is carried out, and FIG. 17 shows a surface of the protective layer after the surface treatment is carried out.

FIG. 18 shows a display device according to an embodiment.

FIG. 19 illustrates a display device according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly explain the present invention, parts irrelevant to the description have been omitted, and the same reference numerals are used for the same or similar constituent elements throughout the specification.

In addition, since the size and thickness of each component shown in the drawing is arbitrarily shown for convenience of description, the present invention is not necessarily limited to the drawings. In the drawings, the thickness of layers, films, panels, regions, and the like are exaggerated for clarity. In addition, in the drawing, the thickness of some layers and regions is exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “on” a reference portion will be understood to mean disposed above or below the reference portion, and will not necessarily be understood to mean disposed “at an upper side” based on an opposite to gravity direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Further, throughout the specification, the phrase “on a plane” means viewing a target portion from the top, and the phrase “on a cross-section” means viewing a cross-section formed by vertically cutting a target portion from the side.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a manufacturing method of a display device according to the present embodiment will be described with reference to the accompanying drawings.

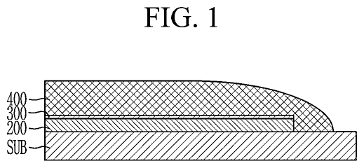

FIG. 1 to FIG. 5 show a manufacturing method of a display device according to an embodiment.

FIG. 1 simply shows a cross-section of a display device according to an embodiment. Referring to FIG. 1, a display panel 200 and an encapsulation layer 300 are disposed on a substrate SUB, and a protective layer 400 is coated and cured on the encapsulation layer 300.

In this case, a thickness of the protective layer 400 may be in a range of about 10 micrometers (μm) to about 150 μm. The protective layer 400 may be formed of an ultraviolet (UV) curable resin, and may be formed by repeating a process of coating the resin and then irradiating and curing the resin once or several times. That is, the protective layer 400 may have a single-layer or multi-layered structure.

The substrate SUB may include or contain glass, and a thickness of the substrate SUB may be in a range of about 30 μm to about 70 μm. The thickness of the substrate SUB of the final display device is thinner, but when the thickness of the substrate SUB is too thin, it may be difficult to smoothly proceed with the process. Therefore, after forming the display panel 200, a separate etching process is carried out on the substrate SUB to make the thickness of the substrate SUB thin. In an embodiment of the invention, the protective layer 400 may be effectively prevented from being peeled off during the etching process of the substrate SUB.

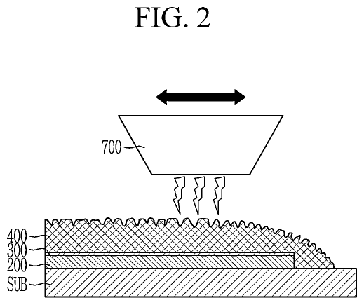

Next, referring to FIG. 2, a surface treatment is carried out on the protective layer 400. In an embodiment, the surface treatment may be plasma treatment or bead treatment. In FIG. 2, an embodiment where the plasma treatment is performed through a plasma generator 700 is shown, but not being limited thereto. Alternatively, the surface treatment may be a bead treatment. Protrusions and depressions may be formed on an upper surface of the protective layer 400 and may have a rough surface due to such a surface treatment. Through the surface treatment, the protective layer 400 may be effectively prevented from being peeled together in a later process. After the surface treatment, a contact angle of the protective layer 400 may be about 10 degrees or less. In an embodiment, for example, the contact angle of the protective layer 400 may be in a range of about 3 degrees to about 7 degrees.

The plasma treatment may be performed by radiating O₂/N₂ plasma on an upper surface of the protective layer 400. In an embodiment, the bead treatment may be performed by a method of spraying spherical and polygonal structured beads having various sizes on the surface. In an embodiment, a diameter of the beads may be in a range of about 5 μm to about 80 μm. The beads may include or be made of at least one material selected from Si, AlOx, rubber, and a metal. In an embodiment, the spraying of the beads may be performed in the process of air injection, bead injection, mixing in a basket, and discharge through a discharge port (injection nozzle). An angle at which the beads are sprayed onto the surface of the protective layer 400 may be in a range of about 45 degrees to about 135 degrees.

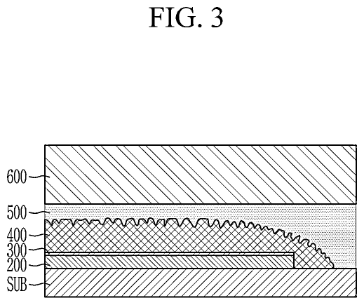

Next, referring to FIG. 3, an adhesive layer 500 and an acid resistant film 600 are attached on the protective layer 400. In an embodiment, the adhesive layer 500 may include a pressure sensitive adhesive (PSA), and the acid resistant film 600 may include polyethylene terephthalate (PET), but not being limited thereto. After being attached, the adhesive layer 500 and the acid resistant film 600 may be cured through UV irradiation.

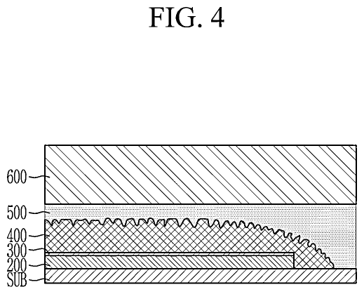

Next, referring to FIG. 4, the substrate SUB is etched. Through such an etching process, the thickness of the substrate SUB can be reduced to half of the existing thickness. In an embodiment, for example, the thickness of the substrate SUB after etching may be in a range of about 10 μm to about 30 μm.

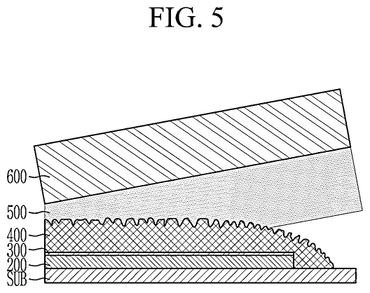

Next, referring to FIG. 5, the adhesive layer 500 and the acid resistant film 600 are removed. In an embodiment, since an upper surface of the protective layer 400 has previously been surface treated with plasma or beads, the protective layer 400 and the adhesive layer 500 are well separated. The surface of the protective layer 400 becomes rough due to the previous surface treatment, and in this case, the protective layer 400 and the adhesive layer 500 are not completely adsorbed, and a separation region occurs between the protective layer 400 and the adhesive layer 500, thereby causing deterioration of adherence.

Therefore, only the adhesive layer 500 and the acid resistant film 600 are selectively removed, and the protective layer 400 may be combined with the encapsulation layer 300 and the substrate SUB.

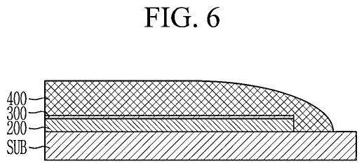

FIG. 6 to FIG. 10 show a separation process when the surface of the protective layer 400 is not treated. Referring to FIG. 6, the display panel 200 and the encapsulation layer 300 are disposed on the substrate SUB, and the protective layer 400 is coated and cured on the encapsulation layer 300.

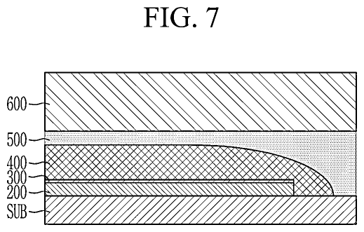

Next, referring to FIG. 7, the adhesive layer 500 and the acid resistant film 600 are attached onto the protective layer 400. After attaching, the adhesive layer 500 and the acid resistant film 600 are cured through UV irradiation.

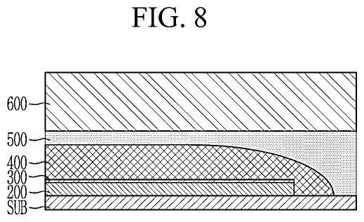

Next, referring to FIG. 8, the substrate SUB is etched. Through such an etching process, the thickness of the substrate SUB is reduced to half of the existing thickness.

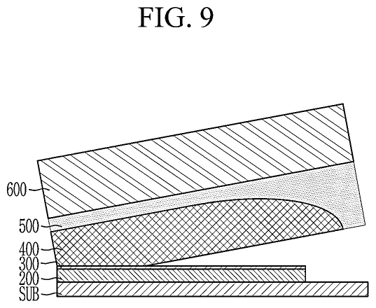

Next, referring to FIG. 9, the adhesive layer 500 and the acid resistant film 600 are removed. In the manufacturing method where the upper surface of the protective layer 400 is not separately surface treated, the adhesive layer 500 and the protective layer 400 are also cured and bonded to each other in the process of curing through UV irradiation after attaching the adhesive layer 500 and acid resistant film 600. Thus, in the process of removing the adhesive layer 500, a defect in which the protective layer 400 is also removed occurs.

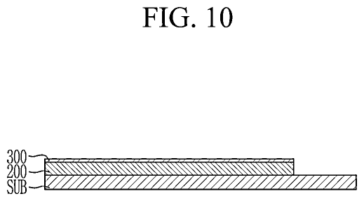

FIG. 10 illustrates the display device of which the protective layer 400 is removed as described above. As shown in FIG. 10, it is not desirable that the adhesive layer 500, the acid resistant film 600, and the protective layer 400 are removed together because the display device cannot be protected in the subsequent process.

In the display device according to an embodiment, the surface treatment of the upper portion of the protective layer 400 with plasma or beads is performed such that the protective layer 400 is effectively prevented from being removed during the removal process of the adhesive layer 500 and the acid resistant film 600.

In FIG. 1 to FIG. 5, an embodiment in which all regions of the protective layer 400 are surface treated is shown, but not being limited thereto.

Alternatively, some regions of the protective layer 400 may be surface treated depending on embodiments.

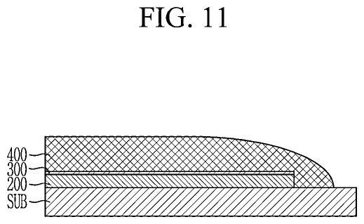

FIG. 11 to FIG. 15 show a method for forming a display device according to an alternative embodiment. A manufacturing method of a display device according to an embodiment of FIG. 11 to FIG. 15 is the same as the manufacturing method of the display device according to the embodiment shown in FIG. 1 to FIG. 5, except that some regions of a protective layer 400 are surface-treated. Any repetitive detailed description of the same constituent elements as those described above will be omitted.

Referring to FIG. 11, a display panel 200 and an encapsulation layer 300 are disposed on a substrate SUB, and the protective layer 400 on the encapsulation layer 300 is coated and cured.

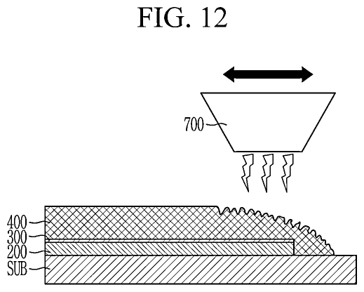

Next, referring to FIG. 12, a surface treatment is carried out on the protective layer 400. In this case, the surface treatment may be a plasma treatment or a bead treatment. Due to such a surface treatment, protrusions and depressions are formed on an upper surface of the protective layer 400 and the protective layer 400 may have a rough surface. Through the surface treatment, the protective layer 400 may be effectively prevented from being peeled together in a later process. After the surface treatment, a contact angle of the protective layer 400 may be about 10 degrees or less. In an embodiment, for example, the contact angle of the protective layer 400 may be in a range of about 3 degrees to about 7 degrees.

In FIG. 12, the surface treatment may be performed only on some regions.

In FIG. 12, regions with the surface treatment and regions without surface treatment are shown separately. In this case, a region where the surface treatment is performed may include a portion where the protective layer 400 contacts the substrate SUB. That is, to prevent the protective layer 400 from being removed, it is desired to perform a surface treatment on an edge portion of the protective layer 400. Therefore, as shown in FIG. 12, it is desirable to surface-treat a portion where the protective layer 400 contacts the substrate SUB.

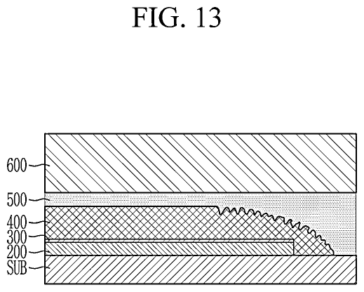

Next, referring to FIG. 13, an adhesive layer 500 and an acid resistant film 600 are attached on the protective layer 400. In this case, the adhesive layer 500 may include PSA and the acid resistant film 600 may include PET, but are not limited thereto. After being attached, the adhesive layer 500 and the acid resistant film 600 may be cured through UV irradiation.

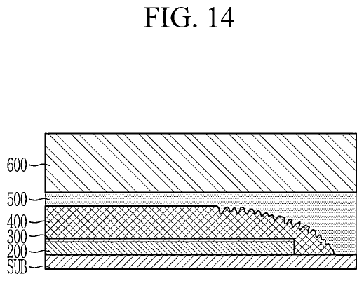

Next, referring to FIG. 14, the substrate SUB is etched. Through such an etching process, the thickness of the substrate SUB can be reduced to half of the existing thickness. In an embodiment, for example, the thickness of the substrate SUB after etching may be in a range of about 10 μm to about 30 μm.

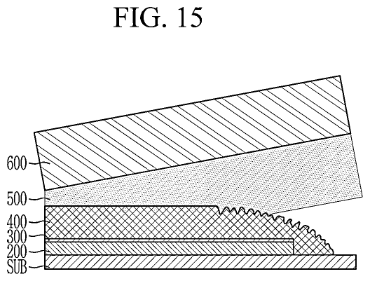

Next, referring to FIG. 15, the adhesive layer 500 and the acid resistant film 600 are removed. In this case, since an upper surface of the protective layer 400 has previously been surface treated with plasma or beads, the protective layer 400 and the adhesive layer 500 are well separated. That is, only the adhesive layer 500 and the acid resistant film 600 are selectively removed, and the protective layer 400 may be combined with the encapsulation layer 300 and the substrate SUB.

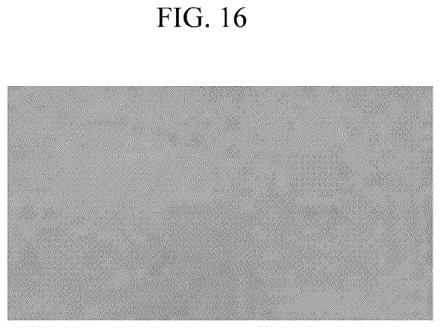

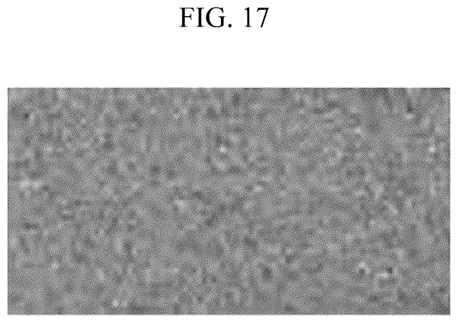

FIG. 16 shows a surface of the protective layer before the surface treatment is carried out, and FIG. 17 shows a surface of the protective layer after the surface treatment is carried out. Comparing FIG. 16 and FIG. 17, the surface of the protective layer is smooth before the surface treatment, but as shown in FIG. 17, it is confirmed that roughness of the surface of the protective layer increases after the surface treatment. In this case, the peel force of the surface-treated surface of the protective layer in such a way may be in a range of about 1 gram-force per inch (g·f/inch) to about 60 g·f/inch.

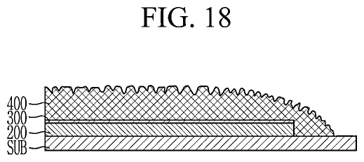

FIG. 18 shows a display device according to an embodiment. Referring to FIG. 18, the display panel 200 and the encapsulation layer 300 are disposed on the substrate SUB, and the protective layer 400 is disposed on the encapsulation layer 300. The surface of the protective layer 400 has roughness after surface treatment. That is, the surface of the protective layer 400 may include protrusions and depressions. In this case, a contact angle of the protective layer 400 may be about 10 degrees or less. In an embodiment, for example, the contact angle may be in a range of about 3 degrees to about 7 degrees. In addition, the peel force of the surface of the protective layer 400 may be in a range of about 1 g·f/inch to about 60 g·f/inch. In an embodiment of FIG. 18, the entire surface of the protective layer 400 is surface-treated, but in alternative embodiments, only a part of the surface of the protective layer 400 may be surface-treated.

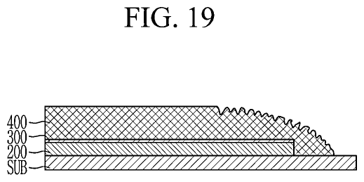

FIG. 19 illustrates a display device according to an alternative embodiment. Referring to FIG. 19, a display device according to an embodiment is the same as the display device according to the embodiment of FIG. 18, except that some regions of a protective layer 400 are surface-treated. Any repetitive detailed description of the same constituent elements as those described above will be omitted. That is, a contact angle of a surface-treated region of the protective layer 400 may be about 10 degrees or less. In an embodiment, for example, a contact angle may be in a range of about 3 degrees to about 7 degrees. In addition, the peel force of the surface-treated region of the protective layer 400 may be in a range of about 1 g·f/inch to about 60 g·f/inch. In this case, the region where the protective layer 400 is surface-treated may include a portion where the protective layer 400 contacts a substrate SUB.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A manufacturing method of a display device, comprising:
forming a display panel on a substrate;
forming a protective layer on the display panel;
forming protrusions and depressions on a surface of the protective layer by performing a surface treatment on the surface of the protective layer;
attaching an adhesive layer and an acid resistant film on the protective layer;
etching the substrate; and
removing the adhesive layer and the acid resistant film.

2. The manufacturing method of the display device of claim 1, wherein
the protective layer comprises an ultraviolet curable resin.

3. The manufacturing method of the display device of claim 2, wherein
the forming the protective layer on the display panel comprises coating the ultraviolet curable resin on the display panel and curing the ultraviolet curable resin through ultraviolet irradiation.

4. The manufacturing method of the display device of claim 1, wherein
the protective layer has a single-layer structure or a multi-layered structure.

5. The manufacturing method of the display device of claim 1, wherein
a thickness of the protective layer is in a range of about 10 μm to about 150 μm.

6. The manufacturing method of the display device of claim 1, wherein
in the forming the display panel on the substrate,
a thickness of the substrate is in a range of about 30 μm to about 70 μm.

7. The manufacturing method of the display device of claim 1, wherein
the substrate comprises glass.

8. The manufacturing method of the display device of claim 1, wherein
after the forming the protrusions and depressions on the surface of the protective layer by performing the surface treatment on the surface of the protective layer,
a contact angle of the protective layer is less than about 10 degrees.

9. The manufacturing method of the display device of claim 8, wherein
the contact angle of the protective layer is in a range of about 3 degrees to about 7 degrees.

10. The manufacturing method of the display device of claim 1, wherein
after the forming the protrusions and depressions on the surface of the protective layer by performing the surface treatment on the surface of the protective layer,
a peel force of a surface-treated region is in a range of about 1 g·f/inch to about 60 g·f/inch.

11. The manufacturing method of the display device of claim 1, wherein
the surface treatment is performed by a plasma treatment or a bead treatment.

12. The manufacturing method of the display device of claim 11, wherein
a diameter of beads used in the bead treatment is in a range of about 5 μm to about 80 μm.

13. The manufacturing method of the display device of claim 11, wherein
beads used in the bead treatment include at least one material selected from Si, AlOx, rubber, and a metal.

14. The manufacturing method of the display device of claim 11, wherein
in the bead treatment, an angle at which beads are sprayed on the surface of the protective layer is in a range of about 45 degrees to about 135 degrees.

15. The manufacturing method of the display device of claim 1, wherein
after the etching the substrate, a thickness of the substrate is in a range of about 10 μm to about 30 μm.

16. The manufacturing method of the display device of claim 1, wherein
in the forming the protrusions and depressions on the surface of the protective layer by performing the surface treatment on the surface of the protective layer, an entire region of the surface of the protective layer is surface-treated.

17. The manufacturing method of the display device of claim 1, wherein
in the forming the protrusions and depressions on the surface of the protective layer by performing the surface treatment on the surface of the protective layer, only a partial region of the surface of the protective layer is surface-treated.

18. The manufacturing method of the display device of claim 17, wherein
the partial region where the protective layer is surface-treated is an edge region of the protective layer including a region where the protective layer is in direct contact with the substrate.

19. A display device comprising:
a substrate;
a display panel disposed on the substrate;
a thin film encapsulation layer disposed on the display panel; and
a protective layer disposed on the thin film encapsulation layer,
wherein a surface of the protective layer comprises protrusions and depressions, and
a contact angle of the protective layer is about 10 degrees or less.

20. The display device of claim 19, wherein
a thickness of the substrate is in a range of about 10 μm to about 30 μm.
